(19) United States
(12) Patent Application Publication
(10) Pub. No.: US 2026/0354213 A1
(43) Pub. Date: Nov. 5, 2026

(54) SUBSTRATE STRUCTURE OF ELECTRONIC DEVICE AND MANUFACTURING METHOD OF ELECTRONIC DEVICE

(71) Applicant: InnoLux Corporation, Miao-Li County (TW)

(72) Inventors: Zi-Zhong WANG, Miao-Li County (TW); Han-Wei TSENG, Miao-Li County (TW); Yi-Liang CHEN, Miao-Li County (TW); Chia-Chi HO, Miao-Li County (TW)

(73) Assignee: InnoLux Corporation, Miao-Li County (TW)

(21) Appl. No.: 19/658,694

(22) Filed: Apr. 26, 2026

Related U.S. Application Data
(60) Provisional application No. 63/798,649, filed on May 2, 2025.

(30) Foreign Application Priority Data
Mar. 13, 2026 (CN) 202610310068.2

(51) Int. Cl. H10W 70/05; C25D 3/38; C25D 5/02; C25D 5/34; C25D 5/50; C25D 5/56; H10W 70/63

(52) U.S. Cl. CPC H10W 70/095; C25D 3/38; C25D 5/02; C25D 5/34; C25D 5/50; C25D 5/56; H10W 70/635

(57) ABSTRACT

A substrate structure of an electronic device comprises a substrate, a plurality of through holes, an auxiliary layer, and a conductive member. The substrate has a first surface and a second surface opposite to each other. The plurality of through holes penetrate the substrate. The auxiliary layer is disposed on the first surface, and at least a portion of the auxiliary layer extends to a sidewall of at least one of the plurality of through holes. The conductive member is disposed in the at least one of the plurality of through holes.

### CROSS REFERENCE TO RELATED APPLICATION

This application claims the benefit of U.S. Provisional Application No. 63/798,649, filed on May 2nd, 2025. The content of the application is incorporated herein by reference.

### BACKGROUND OF THE DISCLOSURE

### 1. Field of the Disclosure

The present disclosure relates to an electronic device, and more particularly, to a design of an electronic device having a substrate structure and a manufacturing method thereof.

### 2. Description of the Prior Art

In the process of forming an electronic device, an electroplating process is used to form conductive members in through holes of a substrate to form a substrate structure.

However, when the through holes to be formed have a high aspect ratio, conductive members formed in the through holes by existing electroplating processes will have voids. This makes signal transmission in an electronic device including the aforementioned substrate structure prone to abnormalities due to defects in the conductive members, which will lead to a decrease in the reliability of the electronic device.

### SUMMARY OF THE DISCLOSURE

According to some embodiments of the present disclosure, a substrate structure of an electronic device comprises a substrate, a plurality of through holes, an auxiliary layer, and a conductive member. The substrate has a first surface and a second surface opposite to each other. The plurality of through holes penetrate the substrate. The auxiliary layer is disposed on the first surface, and at least a portion of the auxiliary layer extends to a sidewall of at least one of the plurality of through holes. The conductive member is disposed in the at least one of the plurality of through holes.

According to some embodiments of the present disclosure, a manufacturing method of an electronic device comprises: providing a substrate structure, wherein the step of providing the substrate structure comprises: providing a substrate having a plurality of through holes, wherein the substrate has a first surface and a second surface opposite to each other, an auxiliary layer is disposed on the first surface, and at least a portion of the auxiliary layer extends to a sidewall of at least one of the plurality of through holes; placing the substrate on a first carrier, wherein the first surface faces a seed layer disposed on the first carrier; and performing an electroplating process to form a conductive member in the at least one of the plurality of through holes, wherein the electroplating process comprises a bottom-up electroplating process; and performing at least one process on the substrate structure to form the electronic device.

### BRIEF DESCRIPTION OF THE DRAWINGS

FIG. 1A is a schematic process flow diagram of a manufacturing method of an electronic device according to an embodiment of the present disclosure;

FIG. 1B is a schematic partial top view of a substrate structure of an electronic device according to some embodiments of the present disclosure;

FIG. 1C is a schematic partial cross sectional view of a substrate structure of an electronic device according to an embodiment of the present disclosure;

FIG. 2 is a schematic diagram of a method for fixing a substrate on a carrier according to an embodiment of the present disclosure;

FIG. 3 is a schematic diagram of another method for fixing a substrate on a carrier according to another embodiment of the present disclosure;

FIG. 4 is a schematic diagram of yet another method for fixing a substrate on a carrier according to yet another embodiment of the present disclosure;

FIG. 5 is a schematic process flow diagram of a manufacturing method of an electronic device according to another embodiment of the present disclosure;

FIG. 6A is a schematic cross sectional view of an electronic device according to an embodiment of the present disclosure; and

FIG. 6B is a schematic partial top view of an electronic device according to an embodiment of the present disclosure.

### DETAILED DESCRIPTION

Reference will now be made in detail to the exemplary embodiments of the present disclosure, examples of which are illustrated in the accompanying drawings. Wherever possible, the same reference numbers are used in the drawings and the description to refer to the same or like parts.

The present disclosure can be understood by referring to the following detailed description in conjunction with the accompanying drawings. It should be noted that, for ease of understanding for the reader and for the conciseness of the drawings, many of the drawings in the present disclosure only depict a portion of an electronic device, and specific components in the drawings are not drawn to actual scale. In addition, the number and size of each component in the figures are for illustrative purposes only and are not intended to limit the scope of the present disclosure.

Throughout the specification and the appended claims of the present disclosure, certain terms are used to refer to specific components. Those skilled in the art should understand that manufacturers of electronic devices may refer to the same component by different names. This document does not intend to distinguish between components that have the same function but different names. In the following specification and claims, terms such as "comprising," "including," "having," and the like are open-ended terms and should therefore be interpreted as "including but not limited to...". Therefore, when the terms "comprises," "comprising," "includes," "including," and/or "has," "having" are used in the description of the present disclosure, they specify the presence of the corresponding features, regions, steps, operations, and/or components, but do not preclude the presence of one or more other corresponding features, regions, steps, operations, and/or components.

The directional terms mentioned herein, such as "upper," "lower," "front," "rear," "left," "right," etc., are only for reference to the orientation in the drawings. Therefore, the directional terms used are for illustrative purposes and not for limiting the present disclosure. In the drawings, each figure shows the general features of the methods, structures, and/or materials used in specific embodiments. However, these drawings should not be construed as defining or limiting the scope or nature covered by these embodiments.

When a corresponding component (e.g., a film layer or a region) is referred to as being "on" another component, it can be directly on the other component, or other components may be present therebetween. On the other hand, when a component is referred to as being "directly on" another component, no other components are present therebetween. In addition, when a component is referred to as being "on" another component, they have a vertical relationship in a top-down view, and this component can be above or below the other component, and this vertical relationship depends on the orientation of the device.

The terms "equal to" or "same," "substantially," or "approximately" are generally interpreted as being within 20% of a given value or range, or as being within 10%, 5%, or 0.5% of a given value or range.

Ordinal numbers such as "first," "second," etc., used in the specification and claims to modify components, do not in themselves imply or represent that the component(s) have any preceding ordinal number, nor do they represent the order of one component relative to another, or the order in a manufacturing method. The use of these ordinal numbers is only to clearly distinguish a component with a certain name from another component with the same name. The claims and the specification may not use the same terms; accordingly, a first component in the specification may be a second component in the claims.

It should be understood that, without departing from the spirit of the present disclosure, features from several different embodiments described below can be substituted to complete other embodiments. As long as the features of the various embodiments do not contradict the spirit of the disclosure or conflict with each other, they can be arbitrarily mixed and matched.

The electrical connections or couplings described in the present disclosure can refer to either direct connections or indirect connections. In the case of a direct connection, the terminals of components on two circuits are directly connected or connected to each other by a conductive line segment. In the case of an indirect connection, other suitable components are present between the terminals of the components on the two circuits.

In the present disclosure, the determination of thickness, length, width, area, and roughness can be observed by an optical microscope, a scanning electron microscope, or a transmission electron microscope. On an uneven surface, the distance difference between the peaks and valleys of the surface undulations can be defined as the roughness of the uneven surface. The condition of the surface undulations is observed under an appropriate magnification of a microscope, and the roughness range is determined by comparing the undulation condition of a sample of a unit length (e.g., 10 micrometers). Here, "appropriate magnification" means a magnification at which at least 10 undulating peaks of the roughness (Rz) or average roughness (Ra) of at least one surface can be seen in the field of view.

The process for the electronic device of the present disclosure can be provided, for example, in a wafer-level package (WLP) process or a panel-level package (PLP) process, which can be a chip-first process or a chip-last/RDL-first process.

The electronic device of the present disclosure can be applied to a power module, a semiconductor package device, a display device, a light-emitting device, a backlight device, an antenna device, a sensing device, or a tiling device, but is not limited thereto. The electronic device can have peripheral systems such as a driving system, a control system, a light source system, etc., to support a display device, an antenna device, a wearable device, a vehicle-mounted device, or a tiling device. The electronic device can include a package device such as a High Bandwidth Memory (HBM) package, a Chip on Wafer on Substrate (CoWoS) package structure, a System on a Chip (SoC), a System in a Package (SiP), an antenna in package (AiP), Co-packaged Optics (CPO), or various combinations of the foregoing devices, but is not limited thereto.

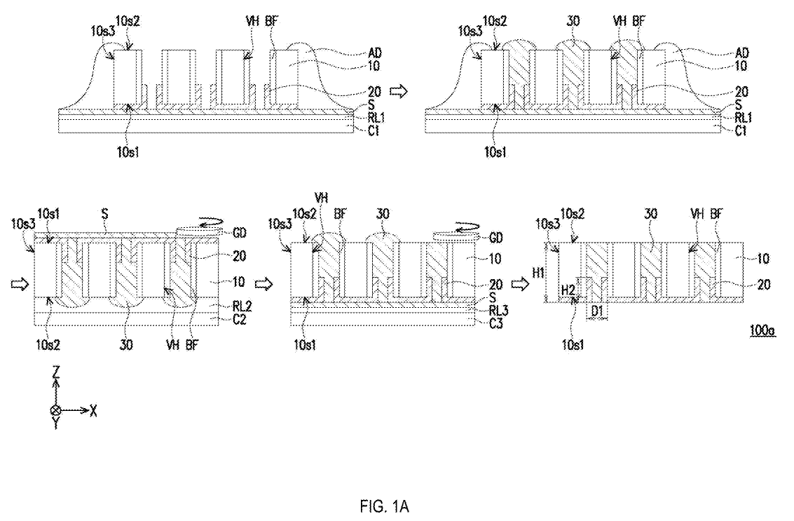

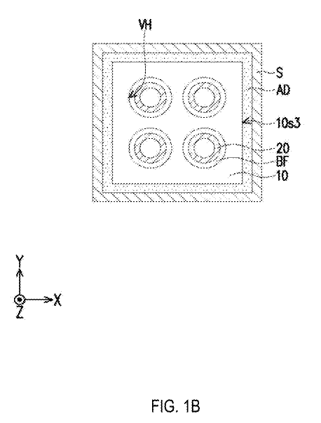

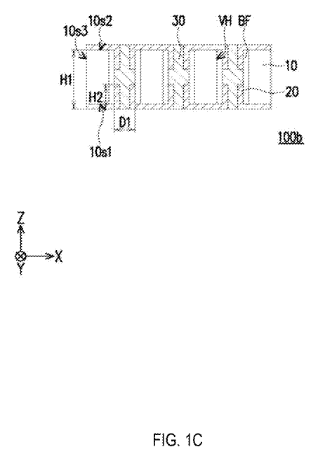

Please refer to FIGS. 1A and 1B. In this embodiment, the substrate structure 100a can be formed by performing the following steps, but the present disclosure is not limited thereto.

Step (1) is performed: a seed layer S is formed on a carrier C1.

The carrier C1 can have a certain rigidity and insulation property. In other words, the rigidity of the carrier C1 can be greater than the rigidity of a redistribution layer or a build-up structure formed thereon, such that when the carrier C1 is used to carry the substrate structure, the redistribution layer, or the build-up structure of this embodiment, the possibility of warpage can be reduced. It is worth noting that "rigidity" as referred to in the present disclosure can be tested by a universal testing machine (UTM). In some embodiments, the material of the carrier C1 can include a transparent material. For example, the material of the carrier C1 can be glass, alkali-free glass, quartz glass, or other suitable materials. In this embodiment, the carrier C1 is a glass carrier.

The seed layer S can be formed on the carrier C1 by performing an electroless plating process, an electroplating process, an atomic layer deposition (ALD) process, a physical vapor deposition (PVD) process, a chemical vapor deposition (CVD) process, or a combination thereof. In some embodiments, the seed layer S can include stacked multiple conductive layers. For example, the seed layer S can include a copper layer and a titanium layer stacked on each other, but the present disclosure is not limited thereto.

In this embodiment, before forming the seed layer S on the carrier C1, the method further includes first forming a release layer RL1 on the carrier C1. In other words, the release layer RL1 is disposed between the seed layer S and the carrier C1.

Through the disposition of the release layer RL1, components subsequently formed on the carrier C1 can be easily separated therefrom. The material of the release layer RL1 can include a matrix selected from organic resins, oxides, or polymer composite materials, and can include a decomposition agent selected from heat-sensitive compounds, photoreactive compounds, redox-active salts, or moisture-sensitive compounds.

Step (2) is performed: a substrate 10 having a plurality of through holes VH is provided, wherein an auxiliary layer 20 is disposed in the plurality of through holes VH.

The material of the substrate 10 can, for example, include a suitable ceramic material. For example, the material of the substrate 10 includes a transparent material, glass, alkali-free glass, quartz glass, or other suitable materials. The coefficient of thermal expansion of the substrate 10 can be between 2 ppm/K and 10 ppm/K, the thickness of the substrate 10 can be between 500 micrometers and 2000 micrometers, and the light transmittance of the substrate 10 can be greater than or equal to 80%, wherein the light includes white light. In this embodiment, the substrate 10 has a surface 10s1, a surface 10s2, and a surface 10s3. Specifically, in the direction Z (the normal direction of the substrate 10), the substrate 10 has the surface 10s1 and the surface 10s2, which are opposite to each other, and has the surface 10s3 connected to the surface 10s1 and the surface 10s2. The surface 10s1 can be regarded as a lower surface of the substrate 10, the surface 10s2 can be regarded as an upper surface of the substrate 10, and the surface 10s3 can be regarded as a side surface of the substrate 10. In some embodiments, substrate processing can be performed by subjecting the substrate 10 to a corresponding etching process and/or laser process, for example, to form a plurality of through holes VH penetrating the substrate 10.

The auxiliary layer 20 is disposed on at least one side of the substrate 10. Specifically, in this embodiment, the auxiliary layer 20 is disposed on the surface 10s1 of the substrate 10, and at least a portion of the auxiliary layer 20 can extend to a sidewall of at least one of the plurality of through holes VH. In some embodiments, the material of the auxiliary layer 20 comprises organic materials or inorganic materials. The inorganic materials can include copper (Cu), titanium (Ti), tungsten (W), metal oxide or a combination thereof. In other embodiments, the auxiliary layer 20 is disposed on the surface 10s2 of the substrate 10, and at least another portion of the auxiliary layer 20 can extend to a sidewall of at least one of the plurality of through holes VH. The organic materials can comprises epoxy, polymer. A roughness of a surface the auxiliary layer 20 is greater than a roughness of a top surface of the conductive member 30.

In some embodiments, in the direction Z, the substrate 10 has a height H1, and the auxiliary layer 20 has a height H2. In a direction perpendicular to the direction Z (e.g., the direction X or the direction Y), the through hole VH has a width D1. In this embodiment, the ratio between the height H1 of the substrate 10, the height H2 of the auxiliary layer 20, and the width D1 of the through hole VH can be 2 : 1.75 : 1, but the present disclosure is not limited thereto. According to the above design, the quality of electroplating process can be improved, for example, the void ratio in the conductive member 30 would be decrease, but the present disclosure is not limited thereto.

In addition, in this embodiment, before forming the auxiliary layer 20, the method further includes first forming a buffer layer BF on the sidewalls of the plurality of through holes VH. The material of the buffer layer BF can include a suitable organic material and/or inorganic material. In some embodiments, the buffer layer BF can include a multilayer stack structure of an inorganic layer/an organic layer/an inorganic layer. By disposing the buffer layer BF to cover the sidewalls of the through holes VH, it can be used to fill pits, unevenness, or micro-cracks generated on the substrate 10 during the formation process of the electronic device, thereby reducing the possibility of the substrate 10 cracking. According to some embodiments, the buffer layer BF can be disposed on at least one surface of the substrate 10.

Step (3) is performed: the substrate 10 is placed on the carrier C1.

In this embodiment, the surface 10s1 of the substrate 10 faces the seed layer S on the carrier C1. That is, the seed layer S can be disposed between the auxiliary layer 20 and the release layer RL1. In some embodiments, an adhesive material AD can be provided on the substrate. According to some embodiments, the adhesive material AD can overlap the substrate 10 and the seed layer S to fix the substrate 10 on the carrier C1, and the adhesive material AD can directly contact the side surface 10s3 of the substrate 10, as shown in the schematic top view of FIG. 1B. In some embodiments, the adhesive material AD includes tape.

Step (4) is performed: a metallization process is performed to form a conductive member 30 in the through hole VH.

In this embodiment, the metallization process includes a bottom-up plating process through an electroplating process. Specifically, by allowing a conductive material (usually copper) to grow from the very bottom of the through hole VH (near the surface 10s1 of the substrate 10), air can be gradually expelled, thereby reducing the possibility of voids being generated in the formed conductive member 30. The disposition of the auxiliary layer 20 can facilitate the bottom-up electroplating process. The formed conductive member 30 can, for example, slightly protrude from the through hole VH and can be formed on a portion of the surface 10s2 of the substrate 10, but the present disclosure is not limited thereto. In some embodiments, the material of the conductive member 30 can include copper (Cu), aluminum (Al), molybdenum (Mo), tungsten (W), gold (Au), chromium (Cr), nickel (Ni), platinum (Pt), titanium (Ti), silver (Ag), tantalum (Ta), a metal nitride, other suitable conductive materials, or a combination of the foregoing. In addition, in some embodiments, the material of the conductive member 30 can be the same as or different from the material of the auxiliary layer 20.

In some embodiments, before performing step (4), the method further includes performing an annealing process on the seed layer S and the auxiliary layer 20.

Specifically, in some embodiments, by performing an annealing process on the seed layer S and the auxiliary layer 20, a eutectic system can be formed. Through the formation of the eutectic system, after the subsequent electroplating process is performed, the conductive member 30 that is relatively stable and/or has relatively good thermal conductivity can be formed.

In some embodiments, the eutectic system can include a binary eutectic system. For example, the binary eutectic system can include Cu/Sn, Cu/Au, Cu/Ag, or other suitable binary eutectic alloys, but the present disclosure is not limited thereto. In other embodiments, the eutectic system can include a ternary eutectic system, which can include a suitable ternary eutectic alloy.

Step (5) is performed: the seed layer S and the auxiliary layer 20 located on the surface 10s1 of the substrate 10 are removed.

In this embodiment, removing the seed layer S and the auxiliary layer 20 located on the surface 10s1 of the substrate 10 can include the following steps. First, a carrier C2 and a release layer RL2 disposed on the carrier C2 are provided. Next, the substrate 10 is placed on the carrier C2, wherein the surface 10s2 of the substrate 10 faces the release layer RL2 on the carrier C2. After that, the substrate 10 is separated from the carrier C1 by using the release layer RL1. Then, a first planarization process is performed to remove the seed layer S and the auxiliary layer 20 located on the surface 10s1 of the substrate 10. In some embodiments, the first planarization process can include performing a grinding process using a grinding element GD, but the present disclosure is not limited thereto.

By removing a portion of the seed layer S and the auxiliary layer 20, the surface of the conductive member 30 exposed by one side of the through hole VH and the surface 10s1 of the substrate 10 can be coplanar.

Step (6) is performed: the conductive member 30 located on the surface 10s2 of the substrate 10 is removed.

In this embodiment, removing the conductive member 30 located on the surface 10s2 of the substrate 10 can include the following steps. First, a carrier C3 and a release layer RL3 disposed on the carrier C3 are provided. Next, the substrate 10 is placed on the carrier C3, wherein the surface 10s1 of the substrate 10 faces the release layer RL3 on the carrier C3. After that, the substrate 10 is separated from the carrier C2 by using the release layer RL2. Then, a second planarization process is performed to remove the conductive member 30 located on the surface 10s2 of the substrate 10. In some embodiments, the second planarization process can include performing a grinding process using a grinding element GD, but the present disclosure is not limited thereto.

By removing a portion of the conductive member 30, the surface of the conductive member 30 exposed by the other side of the through hole VH and the surface 10s2 of the substrate 10 can be coplanar.

In addition, after removing the conductive member 30 located on the surface 10s2 of the substrate 10, the substrate 10 is separated from the carrier C3 by using the release layer RL3. So as to said, a portion of the buffer layer BF is disposed on the sidewall of the at least one of the plurality of through holes VH and located between the conductive member 30 and the substrate 10.

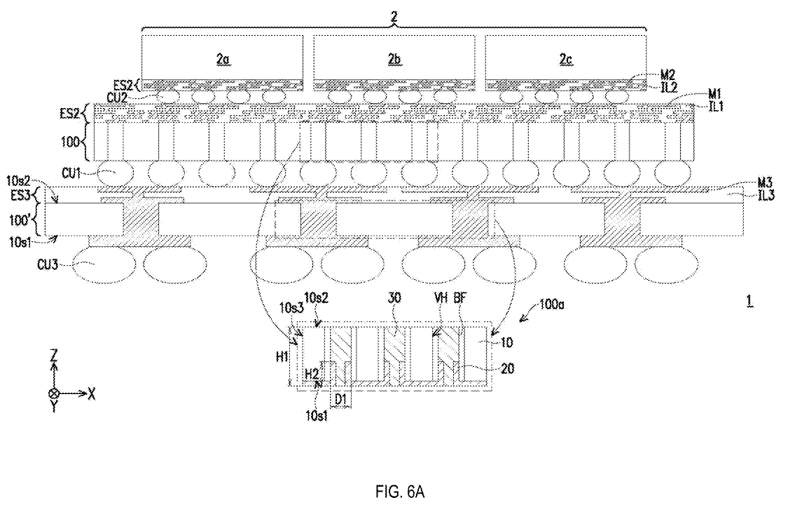

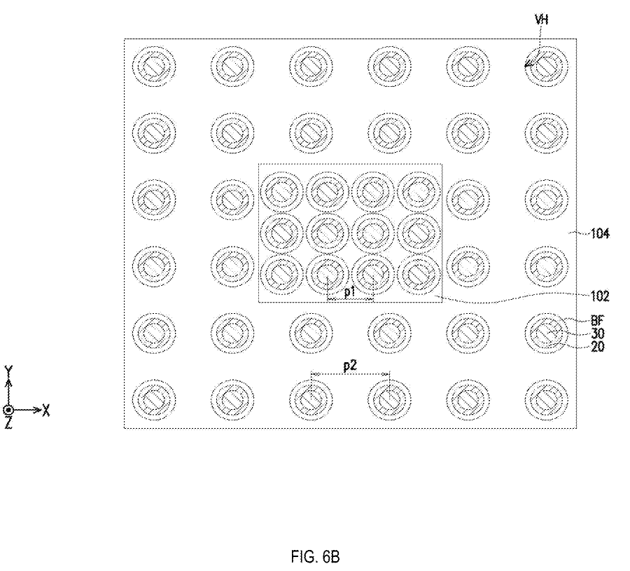

At this point, the fabrication of the substrate structure 100a is completed. In this embodiment, at least one corresponding process can be continued on the substrate structure 100a to form the electronic device 1 as shown in FIGS. 6A and 6B, which will be described in detail in the following embodiments.

Please refer to FIG. 1C. In the substrate structure 100b of other embodiments, the auxiliary layer 20 can also be disposed on the sidewalls of the plurality of through holes VH near the surface 10s2 of the substrate 10, but the present disclosure is not limited thereto.

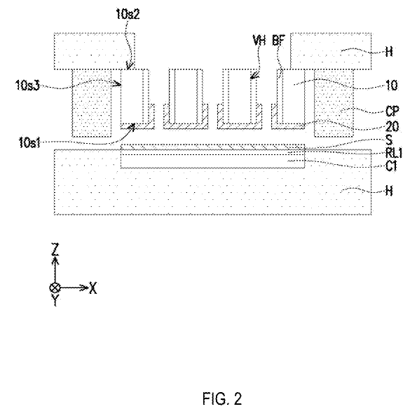

Please refer to FIG. 2, which shows a method of fixing the substrate 10 on the carrier C1. Specifically, in step (3) of this embodiment, a holder H is used to fix the substrate 10 on the carrier C1.

In this embodiment, the holder H can be disposed on the surface 10s2 and the surface 10s3 of the substrate 10 to fix the substrate 10 on the carrier C1, which can reduce the possibility of the substrate 10 being displaced in the subsequent electroplating process. Specifically, the holder H can include an upper portion and a lower portion located on two opposite surfaces (the surface 10s1 and the surface 10s2) of the substrate 10 to securely clamp and fix the substrate 10. In addition, the disposition of the holder H can reduce the possibility of the plating solution used in the electroplating process eroding the corresponding surfaces of the substrate 10.

In addition, in this embodiment, the holder H can include contact pins CP. The contact pins CP can contact the seed layer S disposed on the surface 10s1 of the substrate 10, which can be used to uniformly distribute the current used in the subsequent electroplating process, thereby improving the uniformity of the formed the conductive member 30.

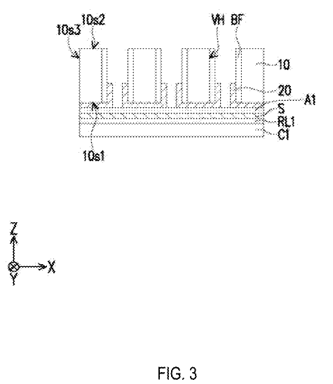

Please refer to FIG. 3, which shows another method of fixing the substrate 10 on the carrier C1. Specifically, in step (1) of this embodiment, the method further includes forming an adhesive layer A1 on the seed layer S.

In this embodiment, the adhesive layer A1 includes a conductive adhesive layer. Specifically, the adhesive layer A1 can, for example, include an insulating film and a plurality of conductive microparticles dispersed therein. For example, the adhesive layer A1 can include an Anisotropic Conductive Film (ACF), but the present disclosure is not limited thereto. In some embodiments, the adhesive layer A1 can have a thermal conductivity of 425-485 W/(m*°C) and can have an impedance of 1.6*10⁻⁶ microohm-cm, but the present disclosure is not limited thereto.

Based on this, after performing step (3), the surface 10s1 of the substrate 10 faces the adhesive layer A1 on the carrier C1. In addition, when performing step (5), the adhesive layer A1 located on the surface 10s1 of the substrate 10 is also removed.

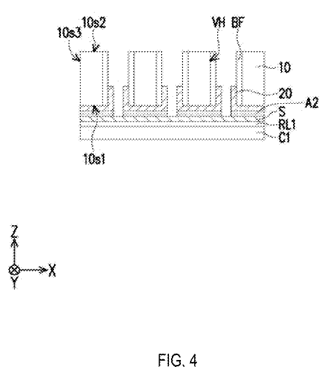

Please refer to FIG. 4, which shows yet another method of fixing the substrate 10 on the carrier C1. Specifically, in step (1) of this embodiment, the method further includes forming an adhesive layer A2 on the seed layer S.

In this embodiment, the material of the adhesive layer A2 includes a thermosetting resin layer. In step (3), after the substrate 10 is placed on the carrier C1, the surface 10s1 of the substrate 10 faces the adhesive layer A2 on the carrier C1. After that, a suitable patterning process is used to remove the adhesive layer A2 exposed by the plurality of through holes VH to facilitate the subsequent electroplating process.

Since the material of the adhesive layer A2 includes a thermosetting resin layer, the disposition of the adhesive layer A2 can be used to block the plating solution used in the electroplating process from flowing into the through holes from the surface 10s3 and/or the surface 10s1 of the substrate 10, thereby reducing the possibility of the plating solution eroding the corresponding surfaces of the substrate 10.

In addition, when performing step (5), the adhesive layer A2 located on the surface 10s1 of the substrate 10 is also removed.

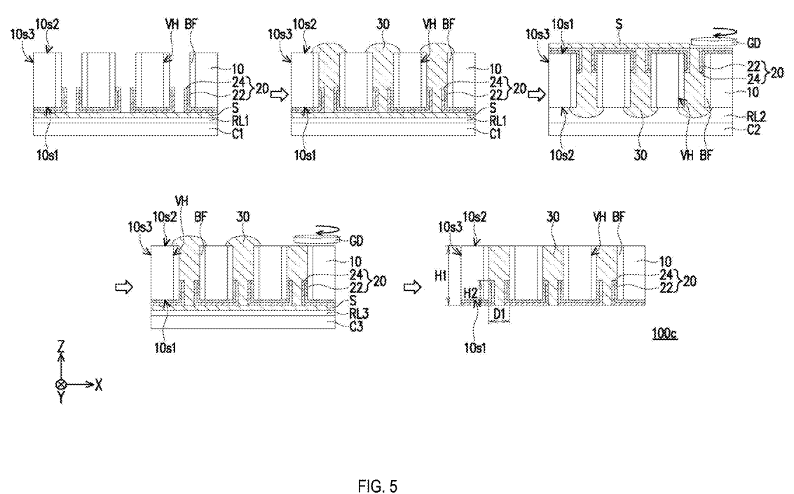

Please refer to FIG. 5, which shows a method for forming a substrate structure 100c. In this embodiment, the main difference between the method for forming the substrate structure 100c and the method for forming the substrate structure 100a is that: in step (2), the auxiliary layer 20 includes a first portion 22 and a second portion 24, and the second portion 24 covers the first portion 22.

In this embodiment, the processes used to form the first portion 22 and the second portion 24 can be different from each other. For example, the first portion 22 can be formed by performing a sputtering process, and the second portion 24 can be formed by performing an electroless plating process, but the present disclosure is not limited thereto. In some embodiments, the materials of the first portion 22 and the second portion 24 can be different from each other. For example, the material of the first portion 22 can include copper, and the material of the second portion 24 can include gold or nickel, but the present disclosure is not limited thereto.

FIG. 6A is a schematic cross sectional view of an electronic device according to an embodiment of the present disclosure, and FIG. 6B is a schematic partial top view of an electronic device according to an embodiment of the present disclosure.

Please refer to FIG. 6A. In this embodiment, at least one corresponding process can be performed on the substrate structure 100 to form the electronic device 1, which can include a process of forming a plurality of electronic components 2 on the substrate structure 100, but the present disclosure is not limited thereto. It is worth noting that the substrate structure 100 can be at least one of the substrate structure 100a, the substrate structure 100b, and the substrate structure 100c described above. In this embodiment, the substrate structure 100 can serve as an interposer of the electronic device 1, but the present disclosure is not limited thereto.

In this embodiment, a circuit structure ES1 is disposed on the surface 10s2 of the substrate 10 and at least partially overlaps the plurality of through holes VH. In some embodiments, the circuit structure ES1 includes at least one insulating layer IL1 and at least one conductive layer M1. The material of the insulating layer IL1 can include an Ajinomoto build-up film (ABF®), a photosensitive polyimide (PSPI), a polyimide (PI), an epoxy resin, or other suitable insulating materials. The conductive layer M1 can include a suitable conductive material, which can be the same as or similar to the material of the conductive member 30.

Please refer to FIG. 6B. In this embodiment, a region of the substrate structure 100 where the plurality of through holes VH are disposed can be divided into a dense region 102 and a sparse region 104. The plurality of through holes VH in the dense region 102 are disposed more densely, and the plurality of through holes VH in the sparse region 104 are disposed more sparsely. Specifically, adjacent two of the plurality of through holes VH located in the dense region 102 have a pitch p1 therebetween, and adjacent two of the plurality of through holes VH located in the sparse region 104 have a pitch p2 therebetween, wherein the pitch p1 is less than half of the pitch p2. It is worth noting that "adjacent" or "neighboring" as referred to in the present disclosure means that two of a plurality of components (e.g., the plurality of through holes VH) are arranged along a direction, and the two have a minimum distance or a minimum spacing. In some embodiments, a conductivity of a material of the auxiliary layer 20 in the plurality of through holes VH located in the dense region 102 is greater than a conductivity of a material of the auxiliary layer 20 in the plurality of through holes VH located in the sparse region 104. According to the above design, the quality of electroplating process can be improved, for example, the void ratio in the conductive member 30 would be decrease, but the present disclosure is not limited thereto.

In this embodiment, the electronic device 1 further includes a plurality of connection units CU1. The plurality of connection units CU1 are disposed on the circuit structure ES1, so that the circuit structure ES1 can be electrically connected to a plurality of electronic components 2, which will be introduced later, through the plurality of connection units CU1. The material of the plurality of connection units CU1 can include tin, copper, nickel, silver, gold, gallium, or other suitable materials.

In this embodiment, the circuit structure ES1 includes a redistribution structure, which can be used for circuit redistribution and/or further increasing the fan-out area of the circuits. The purpose of providing the redistribution structure is to extend connections to a wider pitch or to re-route connections to another connection with a different pitch. Based on this, electronic components 2 that are the same as or different from each other can be disposed on and electrically connected to the circuit structure ES1. Specifically, a plurality of electronic components 2 are disposed on and electrically connected to the circuit structure ES1. In this embodiment, the plurality of electronic components 2 include three electronic components 2a, 2b, and 2c, but the present disclosure is not limited to this number. The electronic components 2a, 2b, and 2c can each be, for example, a System on a Chip (SoC), a dynamic random-access memory (DRAM), a High Bandwidth Memory (HBM), a static random-access memory (SRAM), a Cache Memory, a graphic processing unit (GPU), a central processing unit (CPU), a digital signal processor (DSP), or an application-specific integrated circuit (ASIC), but the present disclosure is not limited thereto. In this embodiment, the three electronic components 2a, 2b, and 2c can be electrically connected to the circuit structure ES1 through corresponding connection units CU1 and a circuit structure ES2. The circuit structure ES2 includes at least one insulating layer IL2 and at least one conductive layer M2, and the material of the insulating layer IL2 and the material of the conductive layer M2 can be respectively the same as or similar to the material of the insulating layer IL1 and the material of the conductive layer M1.

In this embodiment, the electronic device 1 further includes a plurality of connection units CU2. The plurality of connection units CU2 are disposed on one side of the surface 10s1 of the substrate 10 and are electrically connected to the conductive members 30 in the substrate structure 100. The material of the plurality of connection units CU2 can be the same as or similar to the material of the plurality of connection units CU1, and details are not repeated here.

In this embodiment, the electronic device 1 further includes another substrate structure 100'. The substrate structure 100' can also be at least one of the substrate structure 100a, the substrate structure 100b, and the substrate structure 100c described above. In this embodiment, the substrate structure 100' can serve as an integrated circuit substrate (IC substrate) of the electronic device 1, but the present disclosure is not limited thereto.

In this embodiment, the electronic device 1 further includes a circuit structure ES3. The circuit structure ES3 is disposed on the surface 10s2 of the substrate 10 in the substrate structure 100' and at least partially overlaps the plurality of through holes VH. In some embodiments, the circuit structure ES3 includes at least one insulating layer IL3 and at least one conductive layer M3, and the material of the insulating layer IL3 and the material of the conductive layer M3 can be respectively the same as or similar to the material of the insulating layer IL1 and the material of the conductive layer M1.

In this embodiment, the electronic device 1 further includes a plurality of connection units CU3. The plurality of connection units CU3 are disposed on one side of the surface 10s1 of the substrate 10 in the substrate structure 100' and are electrically connected to the conductive members 30 in the substrate structure 100'. The material of the plurality of connection units CU3 can be the same as or similar to the material of the plurality of connection units CU1, and details are not repeated here.

In summary, in the manufacturing method of an electronic device provided by some embodiments of the present disclosure, by disposing the auxiliary layer on the sidewalls of the plurality of through holes near the surface of the substrate, a bottom-up electroplating process can be used to form conductive members in the plurality of through holes. This allows for the uniform formation of conductive members in through holes with a higher aspect ratio, thereby reducing the possibility of voids being generated in the conductive members. Based on this, the reliability of the electronic device provided by some embodiments of the present disclosure can be improved.

What is claimed is:

1. A substrate structure of an electronic device, comprising:
a substrate having a first surface and a second surface opposite to each other;
a plurality of through holes penetrating the substrate;
an auxiliary layer disposed on the first surface, wherein at least a portion of the auxiliary layer extends to a sidewall of at least one of the plurality of through holes; and
a conductive member disposed in the at least one of the plurality of through holes.

2. The substrate structure of an electronic device as claimed in claim 1, wherein the substrate structure comprises a dense region and a sparse region, wherein adjacent two of the plurality of through holes located in the dense region have a first pitch therebetween, adjacent two of the plurality of through holes located in the sparse region have a second pitch therebetween, and the first pitch is less than half of the second pitch.

3. The substrate structure of an electronic device as claimed in claim 2, wherein a conductivity of a material of the conductive member located in the dense region is greater than a conductivity of a material of the conductive member located in the sparse region.

4. The substrate structure of an electronic device as claimed in claim 1, wherein the auxiliary layer is disposed on the sidewall of the plurality of through holes near the second surface.

5. The substrate structure of an electronic device as claimed in claim 1, wherein a material of the auxiliary layer comprises copper (Cu), titanium (Ti), or tungsten (W).

6. The substrate structure of an electronic device as claimed in claim 1, wherein a material of the auxiliary layer is different from a material of the conductive member.

7. The substrate structure of an electronic device as claimed in claim 1, wherein a material of the auxiliary layer comprises a eutectic alloy.

8. The substrate structure of an electronic device as claimed in claim 1, wherein the auxiliary layer comprises a first portion and a second portion, and the second portion covers the first portion.

9. The substrate structure of an electronic device as claimed in claim 8, wherein a material of the first portion is different from a material of the second portion.

10. The substrate structure of an electronic device as claimed in claim 1, wherein the substrate structure further comprises:
a buffer layer disposed on the sidewall of the at least one of the plurality of through holes and located between the conductive member and the substrate.

11. A manufacturing method of an electronic device, comprising:
providing a substrate structure, wherein the step of providing the substrate structure comprises:
providing a substrate having a plurality of through holes, wherein the substrate has a first surface and a second surface opposite to each other, an auxiliary layer is disposed on the first surface, and at least a portion of the auxiliary layer extends to a sidewall of at least one of the plurality of through holes;
placing the substrate on a first carrier, wherein the first surface faces a seed layer disposed on the first carrier; and
performing an electroplating process to form a conductive member in the at least one of the plurality of through holes, wherein the electroplating process comprises a bottom-up electroplating process; and
performing at least one process on the substrate structure to form the electronic device.

12. The manufacturing method of an electronic device as claimed in claim 11, wherein the substrate structure comprises a dense region and a sparse region, wherein adjacent two of the plurality of through holes formed in the dense region have a first pitch therebetween, adjacent two of the plurality of through holes formed in the sparse region have a second pitch therebetween, and the first pitch is less than half of the second pitch.

13. The manufacturing method of an electronic device as claimed in claim 11, wherein after placing the substrate on the first carrier, the method further comprises fixing the substrate on the first carrier by a holder.

14. The manufacturing method of an electronic device as claimed in claim 13, wherein the holder comprises a contact pin, and the contact pin contacts the seed layer.

15. The manufacturing method of an electronic device as claimed in claim 11, further comprising forming an adhesive layer on the seed layer disposed on the first carrier, wherein the adhesive layer comprises a conductive adhesive layer.

16. The manufacturing method of an electronic device as claimed in claim 11, further comprising forming an adhesive layer on the seed layer disposed on the first carrier, wherein the adhesive layer comprises a thermosetting resin layer.

17. The manufacturing method of an electronic device as claimed in claim 11, wherein before performing the electroplating process, the method further comprises performing an annealing process on the seed layer and the auxiliary layer to form a eutectic system.

18. The manufacturing method of an electronic device as claimed in claim 11, wherein the auxiliary layer comprises a first portion and a second portion, and the second portion covers the first portion.

19. The manufacturing method of an electronic device as claimed in claim 18, wherein the first portion is formed by performing a sputtering process, and the second portion is formed by performing an electroless plating process.

20. The manufacturing method of an electronic device as claimed in claim 11, further comprising:
performing a first planarization process to remove the seed layer and the auxiliary layer located on the first surface of the substrate; and
performing a second planarization process to remove the conductive member located on the second surface of the substrate.
